(19) United States
(12) Patent Application Publication
(10) Pub. No.: US 2026/0101463 A1
(43) Pub. Date: Apr. 9, 2026

(54) MODULAR RECONFIGURABLE ACTIVE NETWORK CABINETS

(71) Applicant: Clearfield, Inc., Minneapolis, MN (US)

(72) Inventors: John P. Hill, Oak Grove, MN (US); Cole Heinemann, New Hope, MN (US); Paul D. Swieconek, Petaluma, CA (US); Gary Hasler, Minneapolis, MN (US); Michael Mansfield, Apple Valley, CA (US); Nathan Jacobsen, Saint David, AZ (US)

(21) Appl. No.: 18/909,361

(22) Filed: Oct. 8, 2024

(51) Int. Cl. H05K 7/14

(52) U.S. Cl. CPC H05K 7/1488

(57) ABSTRACT

Systems and methods are provided for active network cabinets with configurable dedicated spaces within a cabinet to accommodate none, one, or multiple battery string housing areas within a cabinet. Certain implementations can utilize separators to define such areas, and/or to configure the remaining cabinet area to be, for example, 20RU, 30RU or 36RU in the same housing footprint, as will be discussed below. The disclosed technology can include joining side-by-side active cabinets together to enable expanding and/or reconfiguring the active network cabinet enclosures, for example, to expand the capacity or update components needed to address changing technology, demand, or operational conditions. Certain implementations of the disclosed technology may utilize a modular cabinet plate to join two side-by-side modular reconfigurable network cabinets together.

### FIELD OF THE INVENTION

The disclosed technology generally relates to configurable network cabinets, and in particular, to outside plant cabinets designed to house and protect optical fiber and network electronics equipment. The cabinets can include a configurable battery compartment. Two or more cabinets may be joined using a modular cabinet plate.

### BACKGROUND

The telecommunications industry often utilizes remote sites, for example, to enable expansion to customers who are located remotely from the main telecommunication plant or center of operations. Remote telecommunication sites are typically contained in a network enclosure to protect the various fragile and sensitive electronics and related components from the elements and other environmental conditions.

In addition to the telecommunication electronics, the network enclosure can include fans, air conditioners, heaters, remote monitoring equipment, batteries, inverters, etc., that can be configured to control the temperature and humidity and/or maintain power in the event of an outage so that service is not interrupted and/or so that the components contained within do not degrade or fail due to environmental conditions.

In conventional network enclosure systems, it can be difficult, if not impossible, to expand or reconfigure traditional network enclosures to add additional components as needed, for example, to expand the capacity or update/add components needed to address changing technology, demand, or operational conditions.

A need exists for configurable network cabinets that can address the needs of the telecommunications industry.

### BRIEF SUMMARY

Embodiments of the disclosed technology include systems and methods configurable network cabinets. Certain implementations of the disclosed technology include a configurable battery compartment. Certain implementations of the disclosed technology enable joining two or more cabinets using a modular cabinet plate.

An active network cabinet is disclosed herein which includes a housing comprising a configurable internal equipment compartment, zero or more configurable internal battery compartments, and a rack unit having a plurality of attachment regions. An active network cabinet having one configurable internal battery compartment includes a first configurable separator disposed between the configurable internal equipment compartment and the configurable internal battery compartment. The first configurable separator defines a first volume of the configurable internal equipment compartment having a first vertical dimension, and a second volume of the configurable internal battery compartment having a second vertical dimension. The first configurable separator may be configured to attach to the rack unit. An active network cabinet having two configurable internal battery compartments includes a first configurable separator disposed between the configurable internal equipment compartment and the two configurable internal battery compartments, and a second configurable separator disposed between the two configurable battery compartments. The first configurable separator defines a first volume of the configurable internal equipment compartment having a first vertical dimension, and a second volume of the two configurable internal battery compartments having a second vertical dimension. The second separator may divide the volume between the two configurable internal battery compartments. The first configurable separator and the second configurable separator may each be configured to attach to the rack unit.

A system is disclosed for joining two active network cabinets. The system includes a modular cabinet plate, one or more gaskets configured to be disposed between the modular cabinet plate and at least one sidewall of the two active network cabinets, and a plurality of fasteners. The modular cabinet plate includes an outer continuous face configured to directly couple with at least one of the one or more gaskets, an inner continuous ledge configured to couple with an aperture boundary defined in the at least one sidewall, and a plurality of through holes distributed around the outer continuous face. The fasteners are configured to be disposed in the through holes to secure the modular cabinet plate to the two active network cabinets.

A joinable and configurable active network cabinet system is disclosed that includes a first active network cabinet comprising a first sidewall, a second sidewall opposing the first sidewall, and a first removeable piece configured to cover and define a first aperture on the first sidewall when the first removeable piece is removed. The system includes a second active network cabinet disposed side-by-side with the first active network. The second active network cabinet comprises a first sidewall, a second sidewall opposing the first sidewall, and a second removeable piece configured to cover and define a second aperture on the second sidewall when the second removable piece is removed. The system includes a modular cabinet plate system having at least a portion disposed in the first aperture and the second aperture and configured to join the first active network cabinet with the second active network cabinet.

Certain exemplary implementations of the disclosed technology include a method for joining two active network cabinets via a modular cabinet plate. The method includes removing a first pass-through aperture cover from a first aperture in a first sidewall of a first active network cabinet, securing a first gasket to an outer portion of the first sidewall around a perimeter of the first aperture, securing the modular cabinet plate to the perimeter of the first aperture with the first gasket therebetween, removing a second pass-through aperture cover from a second aperture in an adjacent sidewall of a second active network cabinet, securing a second gasket to an outer portion of the adjacent sidewall around a perimeter of the second aperture, disposing the second active network cabinet side-by-side with the first active network cabinet such that the first aperture and the second aperture are adjacent and co-aligned with each other, and securing the modular cabinet plate to the perimeter of the second aperture with the second gasket therebetween.

Other implementations, features, and aspects of the disclosed technology are described in detail herein and are considered a part of the claimed disclosed technology. Other implementations, features, and aspects can be understood with reference to the following detailed description, accompanying drawings, and claims.

### BRIEF DESCRIPTION OF THE DRAWINGS

Reference will now be made to the accompanying figures and flow diagrams, which are not necessarily drawn to scale.

FIG. 1 illustrates a perspective view of a modular reconfigurable network cabinet with installed equipment and a lower battery compartment, in accordance with certain implementations of the disclosed technology.

FIG. 2 illustrates a front view of the modular reconfigurable network cabinet as shown in FIG. 1, with a battery compartment cover removed, in accordance with certain exemplary implementations of the disclosed technology.

FIG. 3A illustrates a front view of modular reconfigurable network cabinet configured without a separate battery compartment, in accordance with certain exemplary implementations of the disclosed technology.

FIG. 3B illustrates a front view of modular reconfigurable network cabinet configured with a battery compartment suitable for one string of batteries, in accordance with certain exemplary implementations of the disclosed technology.

FIG. 3C illustrates a front view of modular reconfigurable network cabinet configured with two battery compartments suitable for two strings of batteries, in accordance with certain exemplary implementations of the disclosed technology.

FIG. 4 illustrates two side-by-side modular reconfigurable network cabinets joined together and having a pass-through window defined using a modular cabinet plate, in accordance with certain exemplary implementations of the disclosed technology.

FIG. 5A illustrates a perspective view of a modular cabinet plate that may be utilized to join two side-by-side modular reconfigurable network cabinets together as shown in FIG. 4, in accordance with certain exemplary implementations of the disclosed technology.

FIG. 5B illustrates a front view, a top view, and a side view of a modular cabinet plate as illustrated in FIG. 5A that may be utilized to join two side-by-side modular reconfigurable network cabinets together as shown in FIG. 4, in accordance with certain exemplary implementations of the disclosed technology.

FIG. 5C illustrates installation of a modular cabinet plate as shown in FIGS. 5A and 5B to join two side-by-side modular reconfigurable network cabinets together as shown in FIG. 4, in accordance with certain exemplary implementations of the disclosed technology.

FIG. 5D is a perspective exploded view illustrating how two side-by-side modular reconfigurable network cabinets may be joined using a modular cabinet plate and gaskets, in accordance with certain exemplary implementations of the disclosed technology.

FIG. 6 is a perspective view from inside a portion of two side-by-side modular reconfigurable network cabinets in which bolts and nuts may be used to secure the modular cabinet plate to join two side-by-side modular reconfigurable network cabinets together as shown and discussed above with reference to FIG. 5A-D in accordance with certain exemplary implementations of the disclosed technology.

FIG. 7 is a flow diagram of a method in accordance with certain exemplary implementations of the disclosed technology.

Various features of the technology described herein will become more apparent to those skilled in the art from a study of the Detailed Description in conjunction with the drawings. Those skilled in the art will recognize that alternative embodiments may be employed without departing from the principles of the technology. Accordingly, although specific embodiments are shown in the drawings, the technology is amenable to various modifications.

### DETAILED DESCRIPTION

The disclosed technology includes design architecture that can support multiple active network cabinets with different battery string support in the same housing. Certain implementations may enable reconfiguration of dedicated spaces within a cabinet to accommodate none, one, or multiple battery string housing areas within a cabinet. Certain implementations of the disclosed technology can include using one or more separators to define such areas, and/or to configure the remaining cabinet area to be, for example, 20RU, 30RU or 36RU in the same housing footprint, as will be discussed below. It should be recognized that certain implementations of the disclosed technology may apply to dimensions other than the standard RU measurements.

The disclosed technology enables ganging, coupling, or otherwise joining side-by-side active cabinets together to enable expanding and/or reconfiguring the active network cabinet enclosures, for example, to expand the capacity or update components needed to address changing technology, demand, or operational conditions. Certain implementations of the disclosed technology may utilize a modular cabinet plate to join two side-by-side modular reconfigurable network cabinets together. In certain implementations, the modular cabinet plate can include a pass-through window to allow air conditioning and/or cables to pass from one cabinet to another. In certain implementations, gaskets may be utilized to seal around the modular cabinet plate and between the shell of the enclosure to isolate the joined cabinets from the elements, as will be further discussed below.

The terminology used herein is for the purpose of describing particular implementations and is not intended to be limiting. Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the specification and relevant art and should not be interpreted in an idealized or overly formal sense unless expressly so defined herein. Well-known functions or constructions may not be described in detail for brevity and/or clarity.

Like numbers refer to like elements throughout. In the figures, the thickness of certain lines, layers, components, elements or features may be exaggerated for clarity.

It will be understood that when an element is referred to as being “on”, “attached” to, “connected” to, “coupled” with, “contacting”, “joined,” with etc., another element, it can be directly on, attached to, connected to, coupled with or contacting the other element or intervening elements may also be present. In contrast, when an element is referred to as being, for example, “directly on”, “directly attached” to, “directly connected” to, “directly coupled” with or “directly contacting” another element, there are no intervening elements present. It will also be appreciated by those of skill in the art that references to a structure or feature that is disposed “adjacent” another feature may have portions that overlap or underlie the adjacent feature.

As defined herein, the term “RU” stands for “rack unit” and is a unit of measurement used to describe the height of equipment that is mounted in a cabinet or rack frame, including the configurable network cabinets discussed herein. One RU is 1.75 inches (44.45 mm) tall, and the height of the equipment is expressed as multiples of RUs. For example, a server that is 4U high will take up seven inches of vertical space in the rack.

The disclosed technology is described more fully hereinafter with reference to the accompanying drawings, in which certain example implementations are shown. The disclosed technology may, however, be embodied in many different forms and should not be construed as limited to the embodiments or example set forth herein; rather, these embodiments or examples are provided so that this disclosure will be thorough and complete, and will fully convey the scope of the invention to those skilled in the art.

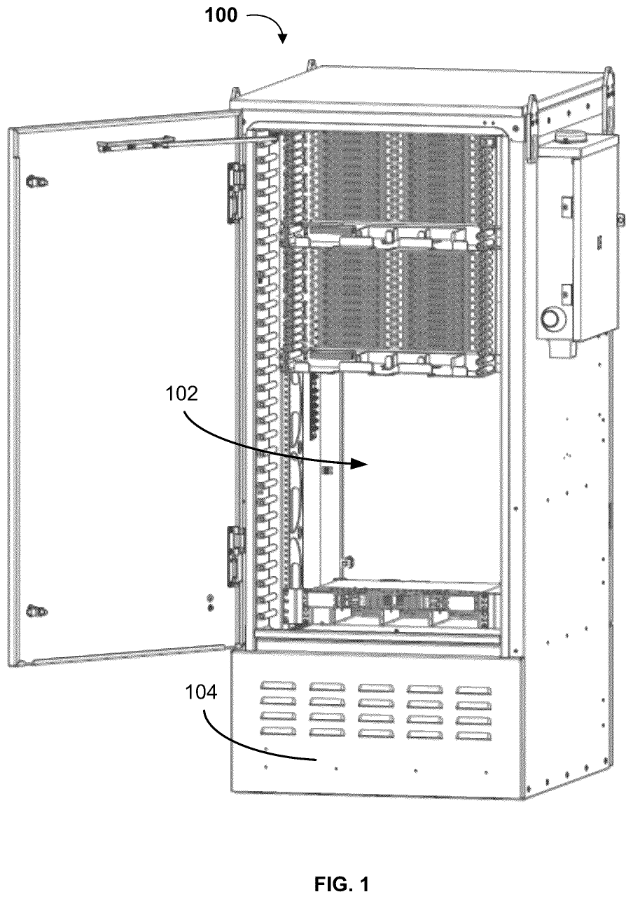

FIG. 1 illustrates a perspective view of an example modular reconfigurable network cabinet 100 with installed equipment in a first compartment 102, and a second compartment 104 that may be utilized for storing one or more batteries, in accordance with certain implementations of the disclosed technology. In certain implementations, the external dimensions of the cabinet 100 may be approximately 72″ high, 30″ wide, and a 36″ depth. The front of the cabinet may provide access to electronics equipment, cabinet power system, fiber management, etc.

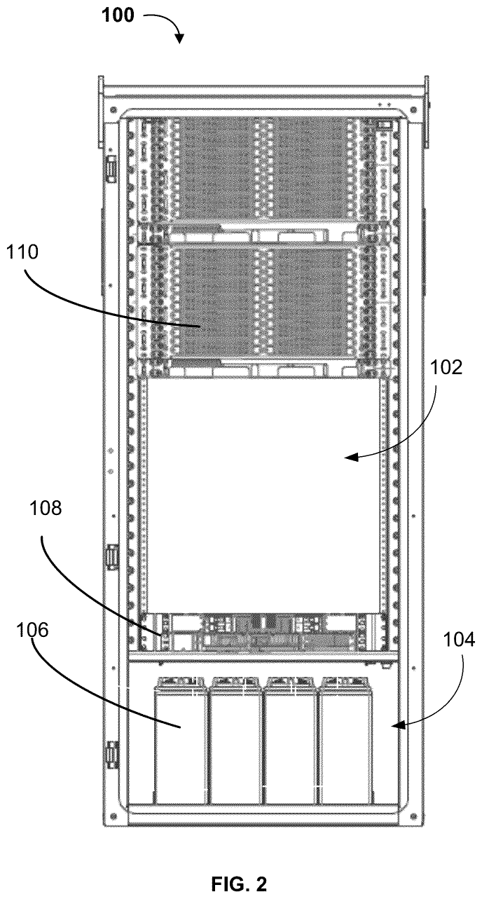

FIG. 2 illustrates a front view of the modular reconfigurable network cabinet 100 as shown in FIG. 1, with a cover of the second compartment 104 removed and a string of batteries 106 installed in the second compartment 104. FIG. 2 also shows active electronics equipment 108 and various fiber management modules 110 installed in the first compartment.

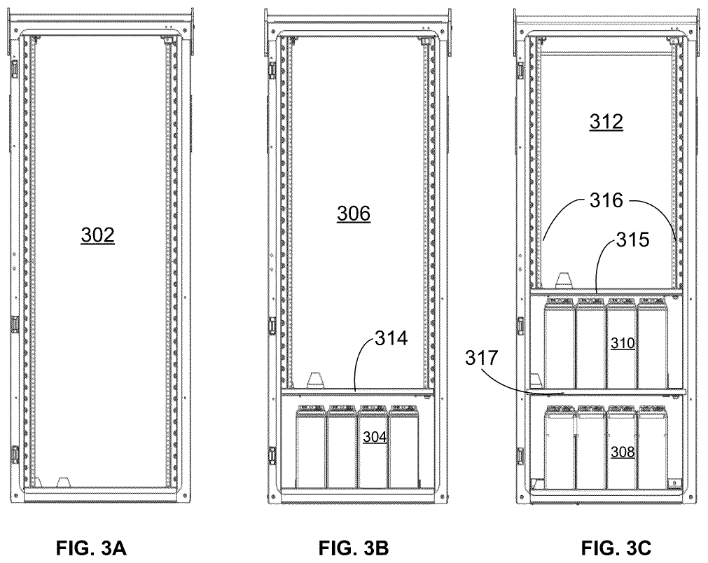

FIG. 3A illustrates a front view of an example modular reconfigurable network cabinet configured with a single first compartment 302 (without a separate battery compartment), in accordance with certain exemplary implementations of the disclosed technology. In certain implementations, the first compartment 302 may be configured to be 36RU in height.

FIG. 3B illustrates a front view of an example modular reconfigurable network cabinet configured with a first compartment 306 and a second compartment 304 suitable for housing a string of batteries, in accordance with certain exemplary implementations of the disclosed technology. In certain implementations, the first compartment 302 may be configured to be 30RU in height. In certain implementations, a divider shelf (i.e., first configurable separator) 314 may be utilized to configure the height dimensions of the first compartment 306 and the second compartment 304 and/or to physically separate the two compartments 304 306.

FIG. 3C illustrates a front view of an example modular reconfigurable network cabinet configured with a first compartment 312, a second compartment 308, and a third compartment 310, where the second compartment 308, and a third compartment 310 may each be suitable for housing a string of batteries, in accordance with certain exemplary implementations of the disclosed technology. In certain implementations, the first compartment 312 may be configured to be 20RU in height. In certain implementations, two divider shelves (i.e., configurable separators) 315 317 may be utilized to configure the height dimensions of the first compartment 312, the second compartment 308, and the third compartment 310 and/or to physically separate the three compartments. In certain implementations, the divider shelve(s) 315 317 may attach to a rack 316 within the cabinet. In certain implementations, the divider shelve(s) 315 317 may be configured to at least partially isolate the corresponding compartments from each other.

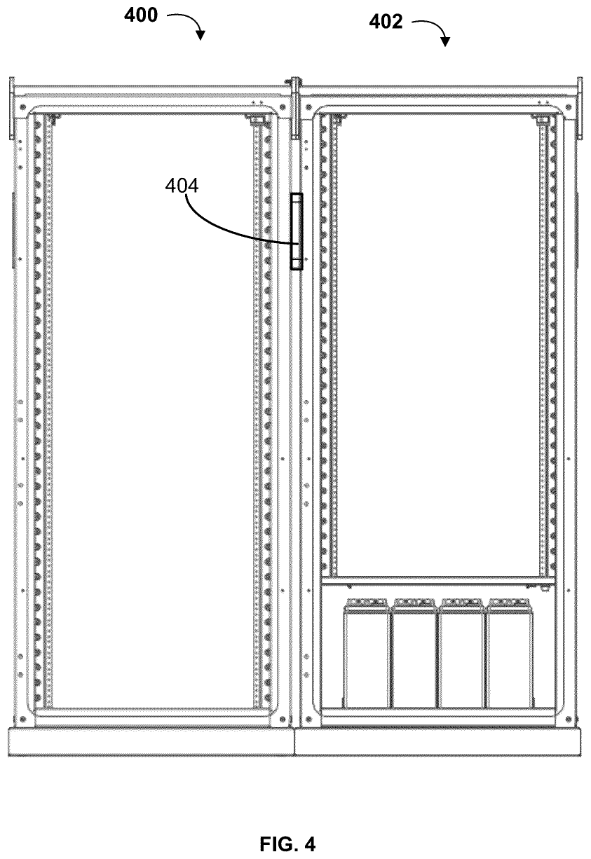

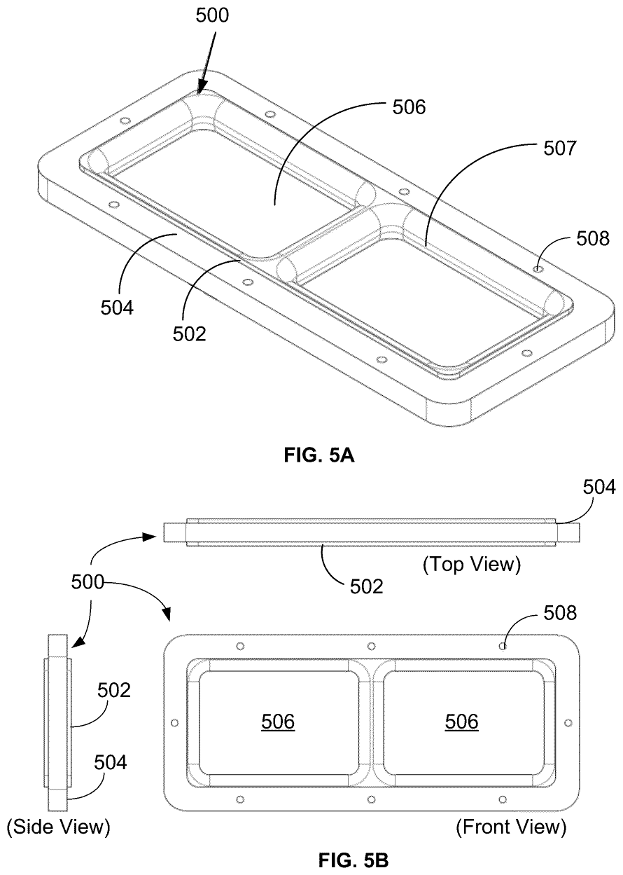

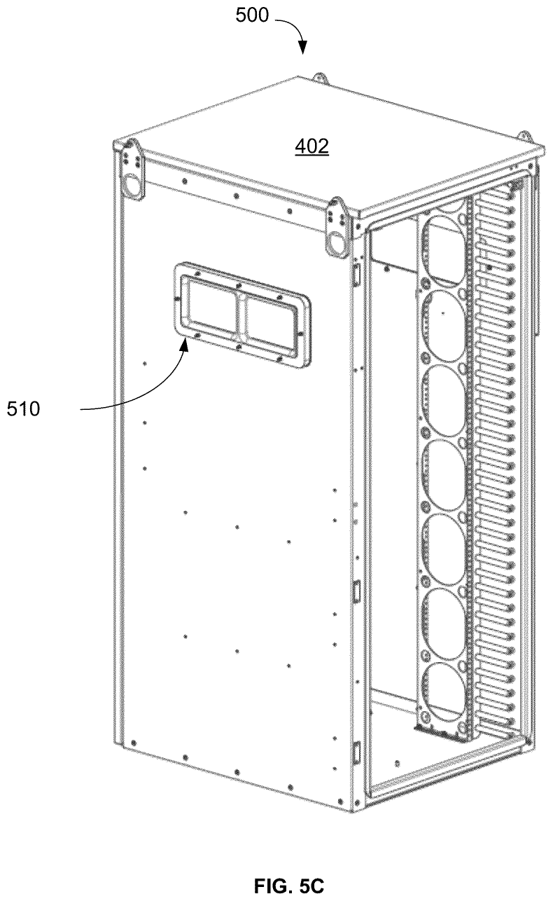

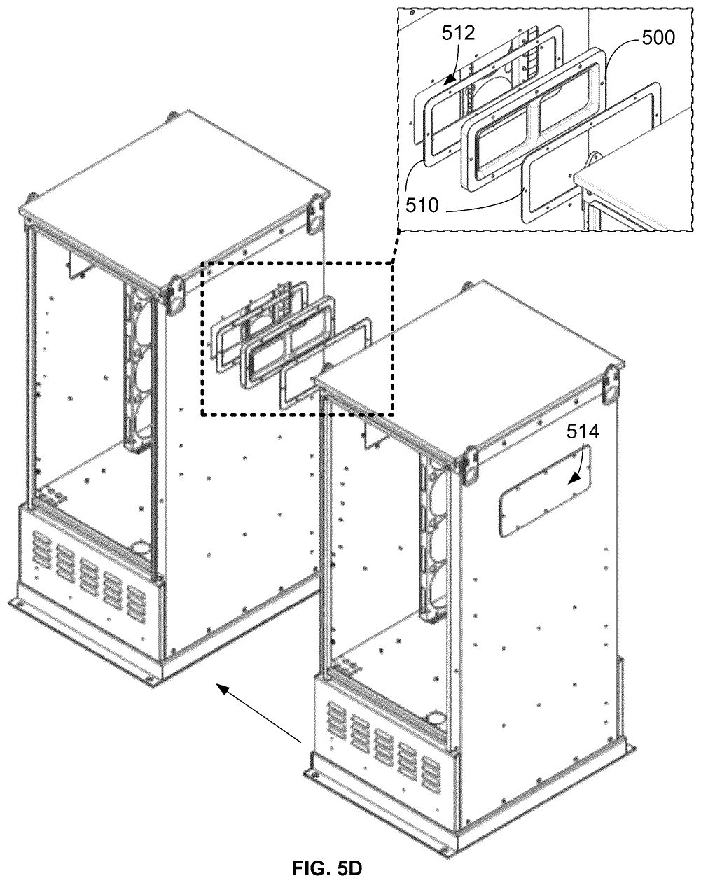

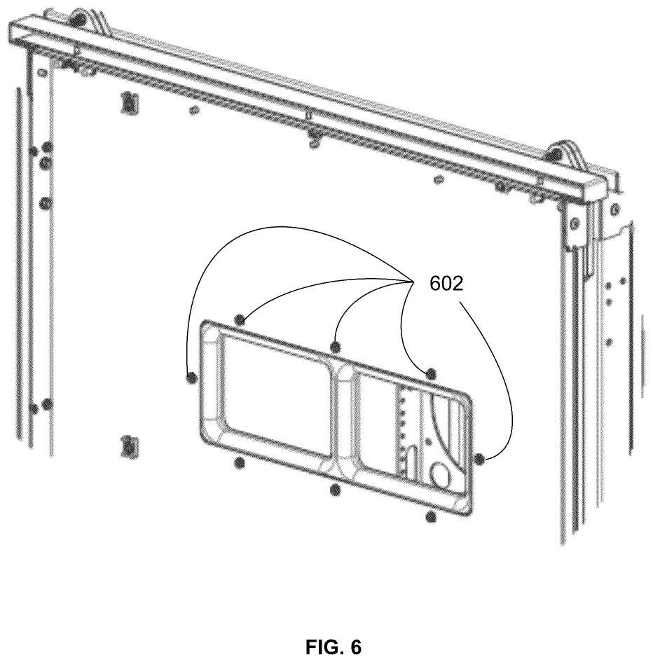

FIG. 4 illustrates two side-by-side modular reconfigurable network cabinets 400 402 joined together and having a pass-through window 404 defined therebetween. In certain implementations, and as will be explained below with reference to FIGS. 5A-6, a modular cabinet plate may be utilized to physically join the two modular reconfigurable network cabinets 400 402, for example, to create a continuous or connected space between the two cabinets 400 402.

FIG. 5A illustrates a perspective view of a modular cabinet plate 500 that may be utilized to join two side-by-side modular reconfigurable network cabinets together as shown in FIG. 4, in accordance with certain exemplary implementations of the disclosed technology. FIG. 5B illustrates a front view, a top view, and a side view of the modular cabinet plate 500 as illustrated in FIG. 5A. In certain implementations, the modular cabinet plate 500 can include raised central portions 502 and flat outer portions 504 on the front and back that can be suitable for retaining gaskets or O-rings, and for coupling with corresponding apertures defined in two side-by-side modular reconfigurable network cabinets, as will be further illustrated and described below with reference to FIG. 5D.

In certain implementations, the modular cabinet plate 500 can include one or more pass-through windows 506 that can allow for a continuous or connected space between two or more joined cabinets. In certain implementations, the one or more pass-through windows 506 may have an inner frame surface 507 with inside rounded corners designed for bend radius protection of optical fiber(s) running through the pass-through window(s) 506, for example, so that the optical fiber does not encounter a sharp corner when draped on inner frame surface 507 of the one or more pass-through windows 506. In certain implementations, the rounded corners and joining surfaces of the inner frame surface 507 may be characterized by a radius of 0.5 inches. In certain implementations, the rounded corners and joining surfaces of the inner frame surface 507 may be characterized by a radius of 0.75 inches. In certain implementations, the rounded corners and joining surfaces of the inner frame surface 507 may be characterized by a radius of 1 inch.

In certain implementations, the modular cabinet plate 500 can include a plurality of mounting holes 508 distributed around the flat outer portions 504 to enable using through bolts to securely sandwich the modular cabinet plate 500 between two side-by-side modular reconfigurable network cabinets and/or to compress the gaskets or O-rings between the outer shells of each cabinet and the flat outer portions 504 on both sides of the modular cabinet plate 500. In certain implementations, the use of the modular cabinet plate 500 and the gaskets or O-rings may isolate the internal compartments from the external environment while allowing two side-by-side cabinets to join to form a continuous inner space that, for example, may allow sharing of air conditioning, heating, and/or may act as a convenient pass-through for connecting components between the two cabinets.

FIG. 5C illustrates part of an installation process of a modular cabinet plate 500, as shown in FIGS. 5A and 5B, to join two side-by-side modular reconfigurable network cabinets together, as shown in FIG. 4, in accordance with certain exemplary implementations of the disclosed technology. In this example installation illustration, the modular cabinet plate 500 is shown being installed from the outside of one of the modular reconfigurable network cabinets (such as cabinet 402 shown in FIG. 4) with a (hidden) gasket 510 sandwiched between the outer shell of a first cabinet 402. and the flat outer portion 504 on one side of the modular cabinet plate 500.

FIG. 5D is an example perspective exploded view (with a detailed inset) illustrating how two side-by-side modular reconfigurable network cabinets may be joined using a modular cabinet plate 500 and sealed with gaskets 510. In accordance with certain implementations of the disclosed technology, one or more sidewalls of each cabinet may have a pre-defined aperture 512 that is normally covered by a removeable cover 514. When two adjacent cabinets are desired to be joined, the corresponding removeable covers 514 may be removed from the adjacent sidewalls to expose the pre-defined aperture 512. As illustrated in the blown-up inset portion, the gaskets 510 may be installed between the sidewall and the modular cabinet plate 500 on both sides so that when the cabinets are joined, the modular cabinet plate 500 is sandwiched between the gaskets 510 and the corresponding sidewalls of each cabinet. In accordance with certain exemplary implementations of the disclosed technology, and as illustrated in FIG. 5A and FIG. 5D the plurality of mounting holes 508 around the periphery of modular cabinet plate 500 may be configured to align with corresponding mounting holes in corresponding sidewalls of each cabinet and the gaskets 510, for example, to allow threading mounting bolts from within one cabinet, through mounting holes in its sidewall, through corresponding holes in the first gasket 510, though the mounting holes 508 around the periphery of modular cabinet plate 500, through corresponding holes in the second gasket 510, and through mounting holes in the sidewall of the second cabinet. In certain implementations, nuts may be used to couple with the mounting bolt end within the second cabinet to further tighten and secure the modular cabinet plate 500 and gaskets 510 between the side-by-side modular reconfigurable network cabinets. In certain implementations, the mounting holes in the sidewalls of the modular reconfigurable network cabinets may be co-located with holes utilized to mount the corresponding removeable covers 514. In other implementations, the mounting holes in the sidewalls of the modular reconfigurable network cabinets may be offset with holes utilized to mount the corresponding removeable covers 514.

FIG. 6 illustrates the installation of bolts and nuts 602 (within the mounting holes 508) around the modular cabinet plate to secure the modular cabinet plate to join two side-by-side modular reconfigurable network cabinets together as shown and discussed above with reference to FIG. 5A-D in accordance with certain exemplary implementations of the disclosed technology. The doors, back, and top of the reconfigurable network cabinets are omitted in FIG. 6 for clarity.

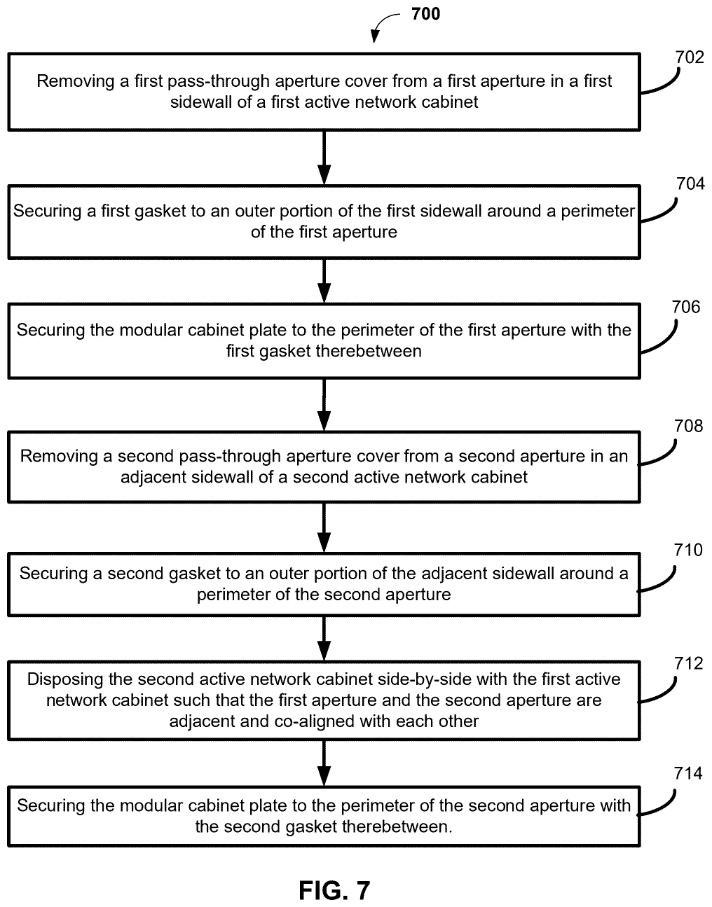

FIG. 7 is a flow diagram of a method 700 for joining two active network cabinets via a modular cabinet plate, in accordance with certain exemplary implementations of the disclosed technology. In block 702, the method 700 includes removing a first pass-through aperture cover from a first aperture in a first sidewall of a first active network cabinet. In block 704, the method 700 includes securing a first gasket to an outer portion of the first sidewall around a perimeter of the first aperture. In block 706, the method 700 includes securing the modular cabinet plate to the perimeter of the first aperture with the first gasket therebetween. In block 708, the method 700 includes removing a second pass-through aperture cover from a second aperture in an adjacent sidewall of a second active network cabinet. In block 710, the method 700 includes securing a second gasket to an outer portion of the adjacent sidewall around a perimeter of the second aperture. In block 712, the method 700 includes disposing the second active network cabinet side-by-side with the first active network cabinet such that the first aperture and the second aperture are adjacent and co-aligned with each other. In block 714, the method 700 includes and securing the modular cabinet plate to the perimeter of the second aperture with the second gasket therebetween.

As discussed herein with reference to FIGS. 1-3C, the disclosed technology includes a configurable, modular, active network cabinet which includes a housing comprising a configurable internal equipment compartment, zero or more configurable internal battery compartments, and a rack unit having a plurality of attachment regions. An active network cabinet having one configurable internal battery compartment, as illustrated in FIG. 3B, may include a first configurable separator 314 disposed between the configurable internal equipment compartment 306 and the configurable internal battery compartment 304. The first configurable separator 314 may define a first volume of the configurable internal equipment compartment 306 having a first vertical dimension, and a second volume of the configurable internal battery compartment 304 having a second vertical dimension. The first configurable separator 314 may be configured to attach to the rack unit 316.

As shown in FIG. 3C, an active network cabinet having two configurable internal battery compartments 308 310 may include a first configurable separator 315 disposed between the configurable internal equipment compartment 312 and the two configurable internal battery compartments 308 310, and a second configurable separator 317 disposed between the two configurable battery compartments 308 310. The first configurable separator 315 may define a first volume of the configurable internal equipment compartment 312 having a first vertical dimension, and a second volume of the two configurable internal battery compartments 308 310 having a second vertical dimension. The second configurable separator 317 may divide the volume between the two configurable internal battery compartments 308 310. The first configurable separator 315 and the second configurable separator 317 may each be configured to attach to the rack unit 316.

In certain implementations, the first configurable separator may be disposed between the configurable internal equipment compartment and the one or more configurable internal battery compartments. The first configurable separator may define the first vertical dimension and the second vertical dimension.

Certain implementations of the disclosed technology can include a second configurable separator to define three compartments. In certain implementations, the second configurable separator may be configured to attach to the rack unit.

In certain implementations, a first door may be attached to the housing to provide access to at least the configurable internal equipment compartment. In certain implementations, a second door may be attached to the housing providing access to the configurable internal equipment compartment and/or the one or more configurable internal battery compartments.

In accordance with certain exemplary implementations of the disclosed technology, the first configurable separator may be mounted to the rack unit within the active network cabinet to selectively define the first vertical dimension to be 20RU or 30RU.

In certain implementations, the first configurable separator may be configured to be removed from the active network cabinet to selectively define the first vertical dimension to be 36RU.

Certain implementations of the disclosed technology include one or more fiber optic modules mounted within the configurable internal equipment compartment.

Certain implementations of the disclosed technology include one or more battery strings mounted within the one or more configurable internal battery compartments.

As discussed herein, a system is disclosed for joining two active network cabinets. The system includes a modular cabinet plate, one or more gaskets configured to be disposed between the modular cabinet plate and at least one sidewall of the two active network cabinets, and a plurality of fasteners. The modular cabinet plate includes an outer continuous face configured to directly couple with at least one of the one or more gaskets, an inner continuous ledge configured to couple with an aperture boundary defined in the at least one sidewall, and a plurality of through holes distributed around the outer continuous face. The fasteners are configured to be disposed in the through holes to secure the modular cabinet plate to the two active network cabinets.

In accordance with certain exemplary implementations of the disclosed technology, the modular cabinet plate can include at least one central pass-through window to allow direct communication between a first active cabinet and a second active cabinet of the two active network cabinets.

Certain implementations of the disclosed technology include at least one bolt and nut pair configured to further secure and join the two active network cabinets, where the at least one bolt and nut pair is configured to join the two active network cabinets via corresponding through holes in sidewalls of two active network cabinets that are connected by the modular cabinet plate.

As discussed herein, a joinable and configurable active network cabinet system is disclosed that includes a first active network cabinet comprising a first sidewall, a second sidewall opposing the first sidewall, and a first removeable piece configured to cover and define a first aperture on the first sidewall when the first removeable piece is removed. The system includes a second active network cabinet disposed side-by-side with the first active network. The second active network cabinet comprises a first sidewall, a second sidewall opposing the first sidewall, and a second removeable piece configured to cover and define a second aperture on the second sidewall when the second removable piece is removed. The system includes a modular cabinet plate system having at least a portion disposed in the first aperture and the second aperture and configured to join the first active network cabinet with the second active network cabinet.

In certain implementations, the modular cabinet plate system can include a modular cabinet plate, one or more gaskets configured to be disposed between the modular cabinet plate and at least one sidewall of the two active network cabinets, and a plurality of fasteners. In certain implementations, the modular cabinet plate may define an outer continuous face configured to directly couple with at least one of the one or more gaskets, an inner continuous ledge configured to couple with a boundary of at least the first aperture, and a plurality of through holes distributed around the outer continuous face. The plurality of fasteners may be configured to be disposed in the plurality of through holes to secure the modular cabinet plate to first active network cabinet and the second active network cabinet.

In accordance with certain exemplary implementations of the disclosed technology, one or more of the first active network cabinet and the second active network cabinet include a housing that can include a configurable internal equipment compartment; one or more configurable internal battery compartments, and a rack unit having a plurality of attachment regions. The one or more of the first active network cabinet and the second active network cabinet can include a first configurable separator disposed between the configurable internal equipment compartment and the one or more configurable internal battery compartments. The first configurable separator may define a first volume of the configurable internal equipment compartment having a first vertical dimension, and a second volume of at least one of the one or more configurable internal battery compartments having a second vertical dimension. In certain implementations, the first configurable separator may be configured to attach to the rack unit.

In certain implementations, the first configurable separator may be disposed between the configurable internal equipment compartment and the one or more configurable internal battery compartments to define the first vertical dimension and the second vertical dimension.

Certain implementations of the disclosed technology can include a second configurable separator disposed between two of the one or more configurable battery compartments, wherein the second configurable separator may be configured to attach to the rack unit.

In certain implementations, the second configurable separator may be disposed between the two of the one or more configurable battery compartments to define a third vertical dimension associated with at least one of the one or more configurable internal battery compartments.

In the foregoing description, references to “an embodiment” or “certain embodiments” mean that the feature, function, structure, or characteristic being described is included in at least one embodiment. Occurrences of such phrases do not necessarily refer to the same embodiment, nor are they necessarily referring to alternative embodiments that are mutually exclusive of one another.

The foregoing description of various embodiments of the claimed subject matter has been provided for the purposes of illustration and description. It is not intended to be exhaustive or to limit the claimed subject matter to the precise forms disclosed. Many modifications and variations will be apparent to one skilled in the art. Embodiments were chosen and described in order to best describe the principles of the invention and its practical applications, thereby enabling those skilled in the relevant art to understand the claimed subject matter, the various embodiments, and the various modifications that are suited to the particular uses contemplated.

Although the Detailed Description describes certain embodiments, the technology can be practiced in many ways no matter how detailed the Detailed Description appears. Embodiments may vary considerably in their implementation details, while still being encompassed by the specification. Particular terminology used when describing certain features or aspects of various embodiments should not be taken to imply that the terminology is being redefined herein to be restricted to any specific characteristics, features, or aspects of the technology with which that terminology is associated. In general, the terms used in the following claims should not be construed to limit the technology to the specific embodiments disclosed in the specification, unless those terms are explicitly defined herein. Accordingly, the actual scope of the technology encompasses not only the disclosed embodiments, but also all equivalent ways of practicing or implementing the embodiments.

The language used in the specification has been principally selected for readability and instructional purposes. It may not have been selected to delineate or circumscribe the subject matter. It is therefore intended that the scope of the technology be limited not by this Detailed Description, but rather by any claims that issue on an application based hereon. Accordingly, the disclosure of various embodiments is intended to be illustrative, but not limiting, of the scope of the technology as set forth in the following claims.

What is claimed:

1. An active network cabinet comprising:
a housing comprising:
a configurable internal equipment compartment;
zero or more configurable internal battery compartments; and
a rack unit having a plurality of attachment regions;
a first configurable separator disposed between the configurable internal equipment compartment and one of the zero or more configurable internal battery compartments, wherein the first configurable separator defines:
a first volume of the configurable internal equipment compartment having a first vertical dimension; and
a second volume of at least one of the zero or more configurable internal battery compartments having a second vertical dimension;
wherein the first configurable separator is configured to attach to the rack unit.

2. The active network cabinet of claim 1, wherein the first configurable separator disposed between the configurable internal equipment compartment and one of the zero or more configurable internal battery compartments defines the first vertical dimension and the second vertical dimension.

3. The active network cabinet of claim 1, further comprising a second configurable separator disposed between two configurable internal battery compartments, wherein the second configurable separator is configured to attach to the rack unit.

4. The active network cabinet of claim 3, wherein the second configurable separator disposed between the two configurable internal battery compartments defines a third vertical dimension associated with at least one of the two configurable internal battery compartments.

5. The active network cabinet of claim 1, further comprising a first door attached to the housing providing access to at least the configurable internal equipment compartment.

6. The active network cabinet of claim 1, further comprising a second door attached to the housing providing access to the configurable internal equipment compartment and the one or more configurable internal battery compartments.

7. The active network cabinet of claim 1, wherein the first configurable separator is mounted to the rack unit within the active network cabinet and selectively defines the first vertical dimension to be 20RU or 30RU.

8. The active network cabinet of claim 7, wherein the first configurable separator is configured to be removed from the active network cabinet to selectively define the first vertical dimension to be 36RU.

9. The active network cabinet of claim 1, further comprising one or more fiber optic modules mounted within the configurable internal equipment compartment.

10. The active network cabinet of claim 1, further comprising one or more battery strings mounted within the one or more configurable internal battery compartments.

11. A system for joining two active network cabinets, comprising:
a modular cabinet plate;
one or more gaskets configured to be disposed between the modular cabinet plate and at least one sidewall of the two active network cabinets; and
a plurality of fasteners;
wherein the modular cabinet plate defines:
an outer continuous face configured to directly couple with at least one of the one or more gaskets;
an inner continuous ledge configured to couple with an aperture boundary defined in the at least one sidewall; and
a plurality of through holes distributed around the outer continuous face; wherein the plurality of fasteners are configured to be disposed in the plurality of through holes to secure the modular cabinet plate to the two active network cabinets.

12. The system of claim 11, wherein the modular cabinet plate has at least one pass-through window to allow direct communication between a first active cabinet and a second active cabinet of the two active network cabinets.

13. The system of claim 12, wherein the at least one pass-through window comprises a radiused internal frame to control a bend radius of an optical fiber disposed in the pass-through window.

14. The system of claim 11, further comprising at least one bolt and nut pair configured to further secure and join the two active network cabinets, wherein the at least one bolt and nut pair is configured to join the two active network cabinets via corresponding through holes in sidewalls of two active network cabinets that are connected by the modular cabinet plate.

15. A joinable and configurable active network cabinet system, comprising:
a first active network cabinet comprising;
a first sidewall;
a second sidewall opposing the first sidewall; and
a first removeable piece configured to define a first aperture on the first sidewall when the first removeable piece is removed;
a second active network cabinet disposed side-by-side with the first active network, the second active network cabinet comprising:
a first sidewall;
a second sidewall opposing the first sidewall; and
a second removeable piece configured to define a second aperture on the second sidewall when the second removable piece is removed;
a modular cabinet plate system having at least a portion disposed in the first aperture and the second aperture and configured to join the first active network cabinet with the second active network cabinet.

16. The joinable and configurable active network cabinet system of claim 15, wherein the modular cabinet plate system comprises:
a modular cabinet plate;
one or more gaskets configured to be disposed between the modular cabinet plate and at least one sidewall of the first active network cabinet; and
a plurality of fasteners;
wherein the modular cabinet plate defines:
an outer continuous face configured to directly couple with at least one of the one or more gaskets;
an inner continuous ledge configured to couple with a boundary of at least the first aperture; and
a plurality of through holes distributed around the outer continuous face;
wherein the plurality of fasteners are configured to be disposed in the plurality of through holes to secure the modular cabinet plate to first active network cabinet and the second active network cabinet.

17. The joinable and configurable active network cabinet system of claim 15, wherein one or more of the first active network cabinet and the second active network cabinet comprises:
a housing comprising:
a configurable internal equipment compartment;
one or more configurable internal battery compartments; and
a rack unit having a plurality of attachment regions;
a first configurable separator disposed between the configurable internal equipment compartment and the one or more configurable internal battery compartments, wherein the first configurable separator defines:
a first volume of the configurable internal equipment compartment having a first vertical dimension; and
a second volume of at least one of the one or more configurable internal battery compartments having a second vertical dimension;
wherein the first configurable separator is configured to attach to the rack unit.

18. The joinable and configurable active network cabinet system of claim 17, wherein the first configurable separator disposed between the configurable internal equipment compartment and the one or more configurable internal battery compartments defines the first vertical dimension and the second vertical dimension.

19. The joinable and configurable active network cabinet system of claim 17, further comprising a second configurable separator disposed between two of the one or more configurable battery compartments, wherein the second configurable separator is configured to attach to the rack unit.

20. The joinable and configurable active network cabinet system of claim 19, wherein the second configurable separator disposed between the two of the one or more configurable battery compartments defines a third vertical dimension associated with at least one of the one or more configurable internal battery compartments.
